(19) United States
(12) Patent Application Publication
(10) Pub. No.: US 2022/0348730 A1
(43) Pub. Date: Nov. 3, 2022

(54) ULTRA-HIGH MODULUS AND RESPONSE PVDF THIN FILMS

(71) Applicant: META PLATFORMS TECHNOLOGIES, LLC, Menlo Park, CA (US)

(72) Inventors: Sheng Ye, Redmond, WA (US); Arman Boromand, Issaquah, WA (US); Christopher Yuan Ting Liao, Seattle, WA (US); Laura Cressman, Carnation, WA (US); Emma Rae Mullen, Seattle, WA (US); Andrew John Ouderkirk, Kirkland, WA (US); Hao Mei, Redmond, WA (US); Cody Wayne Weyhrich, Phoenix, AZ (US); Rui Jian, Fremont, CA (US)

(21) Appl. No.: 17/582,574

(22) Filed: Jan. 24, 2022

Related U.S. Application Data
(60) Provisional application No. 63/182,142, filed on Apr. 30, 2021.

(51) Int. Cl. C08J 5/18; H01L 41/193; H01L 41/333; H01L 41/08

(52) U.S. Cl. CPC C08J 5/18; H01L 41/193; H01L 41/333; H01L 41/0805; G02B 27/0172

(57) ABSTRACT

A polymer thin film includes polyvinylidene fluoride (PVDF) and is characterized by a Young's modulus along an in-plane dimension of at least 4 GPa, an electromechanical coupling factor (k₃₁) of at least 0.1 at room temperature. A method of manufacturing such a polymer thin film may include forming a polymer composition into a polymer thin film, applying a tensile stress to the polymer thin film along at least one in-plane direction and in an amount effective to induce a stretch ratio of at least approximately 5 in the polymer thin film, and applying an electric field across a thickness dimension of the polymer thin film. Annealing and poling steps may separately or simultaneously accompany and/or follow the act of stretching of the polymer thin film.

### CROSS-REFERENCE TO RELATED APPLICATION

This application claims the benefit of priority under 35 U.S.C. § 119(e) of U.S. Provisional Application No. 63/182,142, filed Apr. 30, 2021, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a schematic view of an apparatus for manufacturing a cast PVDF thin film according to certain embodiments.

FIG. 2 is a schematic view of an apparatus for manufacturing a solvent cast PVDF thin film according to some embodiments.

FIG. 3 is an optical micrograph of a comparative cast PVDF thin film according to some embodiments.

FIG. 4 is an optical micrograph of a comparative cast PVDF thin film according to further embodiments.

FIG. 5 is an optical micrograph of a comparative cast PVDF thin film according to still further embodiments.

FIG. 6 is a schematic view of a thin film orientation system for manufacturing anisotropic piezoelectric polymer thin films according to some embodiments.

FIG. 7 is a schematic view of a thin film orientation system for manufacturing anisotropic piezoelectric polymer thin films according to some embodiments.

FIG. 8 shows differential scanning calorimetry endothermy for unstretched, stretched and unannealed, and stretched and annealed polyvinylidene fluoride (PVDF) thin films according to some embodiments.

FIG. 9 is a schematic illustration showing the impact of stretching and annealing on the microstructure of polyvinylidene fluoride according to various embodiments.

FIG. 10 is a plot showing the effect of composition and annealing on the modulus of PVDF thin films according to various embodiments.

FIG. 11 is a bar graph showing the effect of stretching and annealing on the modulus of high molecular weight polyvinylidene fluoride thin films according to various embodiments.

FIG. 12 is a bar graph showing the effect of stretching and annealing on the modulus of polyvinylidene fluoride thin films having a bimodal molecular weight distribution according to various embodiments.

FIG. 13 is an illustration of exemplary augmented-reality glasses that may be used in connection with embodiments of this disclosure.

FIG. 14 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Polymer materials may be incorporated into a variety of different optic and electro-optic systems, including active and passive optics and electroactive devices. Lightweight and conformable, one or more polymer layers may be incorporated into wearable devices such as smart glasses and are attractive candidates for emerging technologies including virtual reality/augmented reality devices where a comfortable, adjustable form factor is desired.

Virtual reality (VR) and augmented reality (AR) eyewear devices and headsets, for instance, may enable users to experience events, such as interactions with people in a computer-generated simulation of a three-dimensional world or viewing data superimposed on a real-world view. By way of example, superimposing information onto a field of view may be achieved through an optical head-mounted display (OHMD) or by using embedded wireless glasses with a transparent heads-up display (HUD) or augmented reality (AR) overlay. VR/AR eyewear devices and headsets may be used for a variety of purposes. Governments may use such devices for military training, medical professionals may use such devices to simulate surgery, and engineers may use such devices as design visualization aids.

These and other applications may leverage one or more characteristics of polymer materials, including the refractive index to manipulate light, thermal conductivity to manage heat, and mechanical strength and toughness to provide light-weight structural support. The degree of optical or mechanical anisotropy achievable through comparative thin film manufacturing processes is typically limited, however, and is often exchanged for competing thin film properties such as flatness, toughness and/or film strength. For example, highly anisotropic polymer thin films often exhibit low strength in one or more in-plane direction, which may challenge manufacturability and limit throughput.

According to some embodiments, oriented piezoelectric polymer thin films may be implemented as an actuatable lens substrate in an optical element such as a liquid lens. Uniaxially-oriented polyvinylidene fluoride (PVDF) thin films, for example, may be used to generate an advantageously anisotropic strain map across the field of view of a lens. However, low piezoelectric response, insufficient mechanical strength or toughness, and/or a lack of adequate optical quality may impede the implementation of PVDF thin films as an actuatable layer.

Notwithstanding recent developments, it would be advantageous to provide optical quality, mechanically robust, and mechanically and piezoelectrically anisotropic polymer thin films that may be incorporated into various optical systems including display systems for artificial reality applications. The instant disclosure is thus directed generally to high modulus, high strength, and optical quality polymer thin films having a high and efficient piezoelectric response as well as their methods of manufacture, and more specifically to casting, calendaring, stretching, annealing and poling methods for forming mechanically stable PVDF-based polymer thin films having a high electromechanical efficiency. A higher modulus may allow greater forces to be generated in the polymer, which may enable thinner, lighter weight, and more efficient devices (e.g., for converting mechanical energy into electrical energy or vice versa).

The piezoelectric response of a polymer thin film may be determined by its chemical composition, the chemical structure of the polymer repeat unit, its density and extent of crystallinity, as well as the alignment of the crystals and/or polymer chains. Among these factors, the crystal or polymer chain alignment may dominate. In crystalline or semi-crystalline polymer thin films, the piezoelectric response may be correlated to the degree or extent of crystal orientation, whereas the degree or extent of chain alignment may create comparable piezoelectric response in amorphous polymers.

An applied stress may be used to create a preferred alignment of crystals or polymer chains within a polymer and induce a corresponding modification of the piezoelectric response along different directions. As disclosed further herein, during processing where a polymer thin film is stretched to induce a preferred alignment of crystals/polymer chains and an attendant modification of the piezoelectric response, Applicants have shown that the choice of the initial polymer composition and microstructure can decrease the propensity for polymer chain entanglement within the cast thin film. In particular embodiments, the polymer material may be characterized by a bimodal distribution of its molecular weight or a high polydispersity index. In some embodiments, evolution of the modulus and the piezoelectric response in PVDF-family polymers may be enhanced by thermal annealing, which may accompany and/or follow the act of stretching.

In accordance with particular embodiments, disclosed are polymer thin film manufacturing methods for forming an optical quality and mechanically robust PVDF-based polymer thin film having a desired piezoelectric response. Whereas in comparative PVDF and related polymer systems, the total extent of crystallization as well as the alignment of crystals may be limited due to polymer chain entanglement, a casting, calendaring, stretching, annealing, and poling method using a polydisperse polymer feedstock may facilitate the disentanglement and alignment of polymer chains, which may lead to improvements in the optical quality and mechanical toughness of a polymer thin film as well as improvements in its piezoelectric efficiency and response.

PVDF-based polymer thin films may be formed using a crystallizable polymer. Example crystallizable polymers may include moieties such as vinylidene fluoride (VDF), trifluoroethylene (TrFE), chlorotrifluoroethylene (CTFE), hexafluoropropene (HFP), and vinyl fluoride (VF). According to various embodiments, a polymer thin film may include one or more of the foregoing moieties, as well as mixtures and co-polymers thereof. According to some embodiments, one or more of the foregoing “PVDF-family” moieties may be combined with a low molecular weight additive to form a piezoelectric polymer thin film. As used herein, reference to a PVDF thin film includes reference to any PVDF-family member-containing polymer thin film unless the context clearly indicates otherwise.

The crystallizable polymer component of such a PVDF thin film may have a molecular weight (“high molecular weight”) of at least approximately 100,000 g/mol, e.g., at least approximately 100,000 g/mol, at least approximately 150,000 g/mol, at least approximately 200,000 g/mol, at least approximately 250,000 g/mol, at least approximately 300,000 g/mol, at least approximately 350,000 g/mol, at least approximately 400,000 g/mol, at least approximately 450,000 g/mol, or at least approximately 500,000 g/mol, including ranges between any of the foregoing values.

The crystallizable polymer may contain a “low molecular weight” polymer or additive. A “low molecular weight” polymer or additive may have a molecular weight of less than approximately 200,000 g/mol, e.g., less than approximately 200,000 g/mol, less than approximately 100,000 g/mol, less than approximately 50,000 g/mol, less than approximately 25,000 g/mol, less than approximately 10,000 g/mol, less than approximately 5000 g/mol, less than approximately 2000 g/mol, less than approximately 1000 g/mol, less than approximately 500 g/mol, less than approximately 200 g/mol, or less than approximately 100 g/mol, including ranges between any of the foregoing values.

Example low molecular weight additives may include oligomers and polymers of vinylidene fluoride (VDF), trifluoroethylene (TrFE), chlorotrifluoroethylene (CTFE), hexafluoropropene (HFP), and vinyl fluoride (VF), as well as homopolymers, co-polymers, tri-polymers, derivatives, and combinations thereof. Such additives may be readily soluble in, and optionally provide refractive index matching with, the high molecular weight component. An example additive may have a refractive index measured at 652.9 nm of from approximately 1.38 to approximately 1.55.

The molecular weight of a low molecular weight additive may be less than the molecular weight of the high molecular weight crystallizable polymer. In some embodiments, the average molecular weight of the low molecular weight polymer (additive) may be approximately 1% to approximately 40% of the average molecular weight of the high molecular weight polymer, e.g., approximately 1%, approximately 3%, approximately 5%, approximately 10%, approximately %, approximately 30%, or approximately 40%, including ranges between any of the foregoing values.

Further example low molecular weight additives may include oligomers and polymers that may have polar interactions with PVDF-family member chains. Such oligomers and polymers may include ester, ether, hydroxyl, phosphate, fluorine, halogen, or nitrile groups. Particular examples include polymethylmethacrylate, polyethylene glycol, and polyvinyl acetate. PVDF polymer and PVDF oligomer-based additives, for example, may include a reactive group such as vinyl, acrylate, methacrylate, epoxy, isocyanate, hydroxyl, amine, and the like. Such additives may be cured in situ, i.e., within a polymer thin film, by applying one or more of heat or light or by reaction with a suitable catalyst.

According to some embodiments, further example low molecular weight additives may include a lubricant. The addition of one or more lubricants may provide intermolecular interactions with PVDF-family member chains and a beneficially lower melt viscosity. Example lubricants include metal soaps, hydrocarbon waxes, low molecular weight polyethylene, fluoropolymers, amide waxes, fatty acids, fatty alcohols, and esters.

Still further example polar additives may include ionic liquids, such as 1-octadecyl-3-methylimidazolium bromide, 1-butyl-3-methylimidazolium[PF₆], 1-butyl-3-methylimidazolium[BF₄], 1-butyl-3-methylimidazolium[FeCl₄] or [1-butyl-3-methylimidazolium[Cl]. According to some embodiments, if used, the amount of an ionic liquid may range from approximately 1 to 15 wt. % of the polymer thin film.

In some examples, the low molecular weight additive may include an inorganic compound. An inorganic additive may increase the piezoelectric performance of a polymer thin film. Example inorganic additives may include nanoparticles (e.g., ceramic nanoparticles such as PZT, BNT, or quartz; or metal or metal oxide nanoparticles), ferrite nanocomposites (e.g., Fe₂O₃—CoFe₂O₄), and hydrated salts or metal halides, such as LiCl, Al(NO₃)₃-9H₂O, BiCl₃, Ce or Y nitrate hexahydrate, or Mg chlorate hexahydrate. The amount of an inorganic additive, if used, may range from approximately 0.001 to approximately 5 wt. % of the polymer thin film.

Generally, a low molecular weight additive may constitute up to approximately 90 wt. % of the polymer thin film, e.g., approximately 0.001 wt. %, approximately 0.002 wt. %, approximately 0.005 wt. %, approximately 0.01 wt. %, approximately 0.02 wt. %, approximately 0.05 wt. %, approximately 0.1 wt. %, approximately 0.2 wt. %, approximately 0.5 wt. %, approximately 1 wt. %, approximately 2 wt. %, approximately 5 wt. %, approximately 10 wt. %, approximately 20 wt. %, approximately 30 wt. %, approximately 40 wt. %, approximately 50 wt. %, approximately 60 wt. %, approximately 70 wt. %, approximately 80 wt. %, or approximately 90 wt. %, including ranges between any of the foregoing values.

In some embodiments, one or more additives may be used. According to particular examples, an original additive can be used during processing of a thin film (e.g., during casting, calendaring, stretching, annealing and/or poling). Thereafter, the original additive may be removed and replaced by a secondary additive. Micro and macro voids produced during solvent removal or a stretching process can be filled by the secondary additive, for example. A secondary additive may be index matched to the crystalline polymer and may, for example, have a refractive index ranging from approximately 1.38 to approximately 1.55. A secondary additive can be added by soaking the thin film in a melting condition or in a solvent bath. A secondary additive may have a melting point of less than approximately 100° C.

In some embodiments, a piezoelectric polymer thin film may include an antioxidant. Example antioxidants include hindered phenols, phosphites, thiosynergists, hydroxylamines, and oligomer hindered amine light stabilizers (HALS).

In certain examples, the molecular weight distribution for the high and low molecular weight polymers may be independently chosen from mono-disperse, bimodal, or polydisperse. A polymer (e.g., a high molecular weight polymer) having a bimodal molecular weight distribution may be characterized by two molecular weight distribution maxima, one in a low(er) molecular weight region and one in a high(er) molecular weight region.

The polydispersity (or heterogeneity index) is a measure of the broadness of a molecular weight distribution of a polymer and may be used to characterize a polymer composition. The polydispersity index (PDI) may be calculated as the ratio of weight average molecular weight (M_{w}) to number average molecular weight (Mₙ) of a polymer sample, i.e., PDI=M_{w}/Mₙ. In accordance with certain embodiments, example high molecular weight polymers may have a polydispersity index of at least approximately 2, e.g., approximately 2, approximately 2.5, approximately 3, approximately 3.5, or approximately 4 or more, including ranges between any of the foregoing values.

In some embodiments, the crystallizable polymer and the low molecular weight additive may be independently selected to include vinylidene fluoride (VDF), trifluoroethylene (TrFE), chloride trifluoride ethylene (CTFE), hexafluoropropene (HFP), vinyl fluoride (VF), as well as homopolymers, co-polymers, tri-polymers, derivatives, and combinations thereof. The high molecular weight component of the polymer thin film may have a molecular weight of at least 100,000 g/mol, whereas the low molecular weight additive may have a molecular weight of less than 200,000 g/mol and may constitute 20 wt. % to 90 wt. % of the polymer thin film.

According to one example, the crystallizable polymer may have a molecular weight of at least approximately 100,000 g/mol and the additive may have a molecular weight of less than approximately 25,000 g/mol. According to a further example, the crystallizable polymer may have a molecular weight of at least approximately 300,000 g/mol and the additive may have a molecular weight of less than approximately 200,000 g/mol. Use herein of the term “molecular weight” may, in some examples, refer to a weight average molecular weight.

A polymer thin film may be formed by casting from a polymer solution or melt. A polymer solution, for instance, may include one or more high molecular weight polymers, one or more low molecular weight additives, and one or more liquid solvents. As disclosed herein, the polymer solution or melt may include a mixture of (i) high molecular weight PVDF (and/or its copolymers) and (ii) low molecular weight PVDF (and/or its copolymers) or mixtures thereof with one or more low molecular weight additives, including miscible polymers, oligomers, and curable monomers.

Suitable liquid solvents may include a chemical compound or mixture of chemical compounds that can at least partially dissolve or substantially swell the polymer, oligomer, and monomer constituent(s). In some embodiments, a liquid solvent may have a vapor pressure of at least approximately 10 mTorr at 100° C.

The liquid solvent (i.e., “solvent”) may include a single solvent compound or a mixture of different solvents. In some embodiments, the solubility of the crystallizable polymer in the liquid solvent may be at least approximately 0.1 g/100 g (e.g., 1 g/100 g or 10 g/100 g) at a temperature of approximately 25° C. or more (e.g., 50° C., 75° C., 100° C., or 150° C., including ranges between any of the foregoing values). The choice of solvent may affect the maximum crystallinity and percent beta phase content of a PVDF-based polymer thin film, which may impact its modulus and/or piezoelectric response. In addition, the polarity of the solvent may impact the critical polymer concentration for polymer chains to entangle in solution.

Example solvents include, but are not limited to, dimethylformamide (DMF), cyclohexanone, dimethylacetamide (DMAc), diacetone alcohol, di-isobutyl ketone, tetramethyl urea, ethyl acetoacetate, dimethyl sulfoxide (DMSO), trimethyl phosphate, N-methyl-2-pyrrolidone (NMP), butyrolactone, isophorone, triethyl phosphate, carbitol acetate, propylene carbonate, glyceryl triacetate, dimethyl phthalate, acetone, tetrahydrofuran (THF), methyl ethyl ketone, methyl isobutyl ketone, glycol ethers, glycol ether esters, and N-butyl acetate.

According to some embodiments, a method of manufacturing a piezoelectric polymer article may include extruding a polymer solution or melt through an orifice to form a cast polymer article, and subsequently heating and stretching the cast polymer article. A casting method may provide control of one or more of the solvent, polymer concentration, and casting temperature, for example, and may facilitate decreased entanglement of polymer chains and allow the polymer thin film to achieve a higher stretch ratio during a subsequent deformation step.

A polymer composition having a bimodal molecular weight or high polydispersity index may be formed into a single layer using casting operations. Alternatively, a polymer composition having a bimodal molecular weight or high polydispersity index may be cast with other polymers or other non-polymer materials to form a multilayer thin film. The application of a uniaxial or biaxial stress to a cast single or multilayer thin film may be used to align polymer chains and/or re-orient crystals to induce mechanical and piezoelectric anisotropy therein. Annealing of a cast polymer thin film may be used to increase total crystallinity and increase crystallite size.

A piezoelectric polymer thin film may be formed from a composition that includes a crystallizable polymer and a low molecular weight additive. In particular embodiments, a piezoelectric polymer thin film having a high electromechanical efficiency may be formed by casting. An example method may include forming a solution of a crystallizable polymer and a solvent, removing a portion of the solvent to form a cast polymer thin film, orienting, annealing, and then poling the thin film. The choice of solvent may facilitate chain disentanglement and accordingly polymer chain and dipole alignment, e.g., during orienting. During an orienting step, the cast polymer may include less than approximately 10 wt. % liquid solvent.

After casting, the PVDF film can be oriented either uniaxially or biaxially as a single layer or multilayer to form a piezoelectrically anisotropic film. In some embodiments, the surface of the PVDF thin film may be treated by calendaring.

According to some examples, a calendaring process may be used to orient polymer chains at room temperature or at elevated temperature. According to further examples, a solid state extrusion process may be used to orient the polymer chains. A liquid solvent may be partially or fully removed before, during, or after stretching and orienting.

In an example process, a dried or substantially dried polymer material may be hot pressed to form a desired shape that is fed through a solid state extrusion system (i.e., extruder) at a suitable extrusion temperature. A solid state extruder may include a bifurcated nozzle, for example. The temperature for hot pressing and the extrusion temperature may each be less than approximately 190° C. That is, the hot pressing temperature and the extrusion temperature may be independently selected from 180° C., 170° C., 160° C., 150° C., 130° C., 110° C., 90° C., or 80° C., including ranges between any of the foregoing values. According to particular embodiments, the extruded polymer material may be stretched further, e.g., using a post-extrusion, uniaxial or biaxial stretch process.

An anisotropic polymer thin film may be formed using a thin film orientation system configured to heat and stretch a polymer thin film in at least one in-plane direction in one or more distinct regions thereof. In some embodiments, a thin film orientation system may be configured to stretch a polymer thin film, i.e., a crystallizable polymer thin film, along only one in-plane direction. For instance, a thin film orientation system may be configured to apply an in-plane stress to a polymer thin film along the x-direction while allowing the thin film to relax along an orthogonal in-plane direction (i.e., along the y-direction). The relaxation of a polymer thin film may, in certain examples, accompany the absence of an applied stress along a relaxation direction.

According to some embodiments, within an example system, a polymer thin film may be heated and stretched transversely to a direction of film travel through the system. In such embodiments, a polymer thin film may be held along opposing edges by plural movable clips slidably disposed along a diverging track system such that the polymer thin film is stretched in a transverse direction (TD) as it moves along a machine direction (MD) through heating and deformation zones of the thin film orientation system.

According to some embodiments, within an example system, a polymer thin film may be heated and stretched parallel to a direction of film travel through the system. In such embodiments, a polymer thin film may be held along opposing edges by plural movable clips slidably disposed along a converging track system such that the polymer thin film is stretched in a machine direction (MD) as it moves along the machine direction (MD) through heating and deformation zones of the thin film orientation system.

In some embodiments, the stretching rate in the transverse direction and the relaxation rate in the machine direction (or vice versa) may be independently and locally controlled. In some embodiments, the act of stretching may include a constant or changing thin film temperature and/or a constant or changing strain rate. In certain embodiments, large scale production may be enabled using a roll-to-roll manufacturing platform.

In certain aspects, the tensile stress may be applied uniformly or non-uniformly along a lengthwise or widthwise dimension of the polymer thin film. Heating of the polymer thin film may accompany the application of the tensile stress. For instance, a semi-crystalline polymer thin film may be heated to a temperature greater than room temperature (˜23° C.) to facilitate deformation of the thin film and the formation and realignment of crystals and/or polymer chains therein.

The temperature of the polymer thin film may be maintained at a desired value or within a desired range before, during and/or after the act of stretching, i.e., within a pre-heating zone or a deformation zone downstream of the pre-heating zone, in order to improve the deformability of the polymer thin film relative to an un-heated polymer thin film. The temperature of the polymer thin film within a deformation zone may be less than, equal to, or greater than the temperature of the polymer thin film within a pre-heating zone.

In some embodiments, the polymer thin film may be heated to a constant temperature throughout the act of stretching. In some embodiments, different regions of the polymer thin film may be heated to different temperatures, i.e., during and/or subsequent to the application of a tensile stress. In certain embodiments, the stretch ratio in response to the applied tensile stress may be at least approximately 1.2, e.g., approximately 1.2, approximately 1.5, approximately 2, approximately 3, approximately 4, approximately 5, approximately 10, approximately 12, approximately 15, or approximately 20 or more, including ranges between any of the foregoing values. A stretch ratio may be calculated as a length of the polymer thin film after stretching divided by the corresponding length before stretching.

In various examples, a modulus of elasticity of the stretched polymer thin film along a stretch direction thereof may be proportional to the stretch ratio. Higher stretch ratios may effectively unfold relatively elastic lamellar polymer crystals and increase the extent of crystal alignment within the resulting piezoelectric polymer thin film.

In some embodiments, the crystalline content within the polymer thin film may increase during the act of stretching. In some embodiments, stretching may alter the orientation of crystals and/or an average crystallite size within a polymer thin film without substantially changing the crystalline content.

The application of a uniaxial or biaxial stress to a single or multilayer thin film may be used to align polymer chains and/or orient crystals to induce optical and mechanical anisotropy. Such thin films may be used to fabricate anisotropic piezoelectric substrates, high Poisson's ratio thin films, reflective polarizers, and the like, and may be incorporated into unimorph and bimorph actuators, haptic articles (e.g., gloves), AR/VR headsets, AR/VR combiners, or used to provide display brightness enhancement.

A piezoelectric polymer article may be formed by applying a stress to a cast polymer thin film. In some embodiments, a polymer thin film having a bimodal molecular weight distribution, or a high polydispersity index, may be stretched to a larger stretch ratio than a comparative polymer thin film (e.g., lacking a low molecular weight additive). In some examples, a stretch ratio may be greater than 4, e.g., 5, 10, 20, 30, 40, or more. The act of stretching may include a single stretching step or plural (i.e., successive) stretching steps where one or more of a stretching temperature and a strain rate may be independently controlled.

An example method of forming a piezoelectric polymer thin film may include uniaxially orienting a cast polymer thin film with a stretch ratio of at least approximately 4, e.g., 5, 10, 20, 30, 40, or more, including ranges between any of the foregoing values). A further example method of forming a piezoelectric polymer thin film may include biaxially orienting a cast polymer thin film with independent stretch ratios along each in-plane direction of at least approximately 4, e.g., 5, 10, 20, 30, 40, or more, including ranges between any of the foregoing values). Biaxial stretching may be performed simultaneously or in successive stretching steps.

Without wishing to be bound by theory, one or more low molecular weight additives may interact with high molecular weight polymers throughout casting, calendaring, stretching, annealing, and poling processes to facilitate less chain entanglement and better chain alignment and, in some examples, create a higher crystalline content within the polymer thin film. That is, a composition having a bimodal molecular weight distribution or high polydispersity index may be cast to form a thin film, which may be stretched to induce mechanical and piezoelectric anisotropy through crystal and/or chain realignment. Stretching may include the application of a uniaxial stress or a biaxial stress. In some embodiments, the low molecular weight additive may beneficially decrease the draw temperature of the polymer composition during casting. In some embodiments, a polymer thin film may be stretched by extruding.

In example methods, the polymer thin film may be heated during stretching to a temperature of from approximately 60° C. to approximately 170° C. and stretched at a strain rate of from approximately 0.1%/sec to approximately 300%/sec. Moreover, one or both of the temperature and the strain rate may be held constant or varied during the act of stretching. For instance, in an illustrative but non-limiting example, a polymer thin film may be stretched at a first temperature and a first strain rate (e.g., 130° C. and 50%/sec) to achieve a first stretch ratio. Subsequently, the temperature of the polymer thin film may be increased, and the strain rate may be decreased to a second temperature and a second strain rate (e.g., 165° C. and 5%/sec) to achieve a second stretch ratio.

Following deformation of the polymer thin film, the heating may be maintained for a predetermined amount of time, followed by cooling of the polymer thin film. The act of cooling may include allowing the polymer thin film to cool naturally, at a set cooling rate, or by quenching, such as by purging with a low temperature gas, which may thermally stabilize the polymer thin film.

In some embodiments, during and/or following stretching, the polymer thin film may be annealed. Annealing may be performed at a fixed or variable stretch ratio and/or a fixed or variable applied stress. In some embodiments, a polymer thin film may be annealed while under an applied real stress of at least approximately 100 MPa. The annealing temperature may be fixed or variable. A variable annealing temperature, for instance, may increase from an initial annealing temperature to a final annealing temperature. The annealing temperature may be greater than the polymer's glass transition temperature (T_{g}) and, in certain examples, may be less than, substantially equal to, or greater than the temperature corresponding to the onset of melting for the polymer. An example annealing temperature may be greater than approximately 80° C., e.g., 100° C., 130° C., or 170° C., including ranges between any of the foregoing values. Without wishing to be bound by theory, annealing may stabilize the orientation of polymer chains and decrease the propensity for shrinkage of the polymer thin film.

Annealing may include a single step process (i.e., at a single temperature) or a multi-step process. Multi-step annealing may include heating a polymer thin film to successively greater temperatures. During a multi-step anneal, smaller crystals may melt and recrystallize as larger crystals. With such a process, smaller and medium sized crystals may be reformed as larger crystals, which may result in a higher thin film modulus following multiple annealing steps.

Stretching a PVDF-family film may form both alpha and beta phase PVDF crystals, although only aligned beta phase crystals contribute to a piezoelectric response. During and/or after a stretching process, and during and/or after an annealing process, an electric field may be applied to the polymer thin film. The application of an electric field (i.e., poling) may induce the formation and alignment of beta phase crystals within the film. Whereas a lower electric field (<50 V/micrometer) can be applied to align beta phase crystals, a higher electric field (≥50 V/micrometer) can be applied to both induce a phase transformation from the alpha phase to the beta phase and encourage alignment of the beta phase crystals. According to some embodiments, the act of poling may accompany and/or follow stretching of the polymer thin film. According to some embodiments, the act of poling may accompany and/or following annealing of the polymer thin film.

According to further embodiments, a polymer thin film may be exposed to actinic radiation. A polymer thin film may be exposed to actinic radiation prior to, during, and/or following the act of stretching. Moreover, actinic radiation exposure may occur prior to, during, and/or after annealing. Example of suitable actinic radiation include gamma, beta, and alpha radiation, electron beams, UV light, and x-rays.

Following deformation, the crystals or chains may be at least partially aligned with the direction of the applied tensile stress. As such, a polymer thin film may exhibit a high degree of optical clarity, bulk haze of less than approximately 10%, a Young's modulus along an in-plane dimension of at least approximately 4 GPa, a high piezoelectric coefficient (e.g., d₃₁ greater than approximately 5 pC/N) and/or a high electromechanical coupling factor (e.g., k₃₁ greater than approximately 0.2).

By way of example, an oriented polymer thin film having a bimodal molecular weight distribution may have an in-plane modulus greater than approximately 4 GPa, e.g., 4, 5, 10, 12, or 15 GPa, including ranges between any of the foregoing values, and a piezoelectric coefficient (d₃₁) greater than 5 pC/N, e.g., 5, 10, 15, or 20 pC/N, including ranges between any of the foregoing values. High piezoelectric performance may be associated with the creation and alignment of beta phase crystals in PVDF-family polymers.

Further to the foregoing, an electromechanical coupling factor kᵢⱼ may indicate the effectiveness with which a piezoelectric material can convert electrical energy into mechanical energy, or vice versa. For a polymer thin film, the electromechanical coupling factor k₃₁ may be expressed as k₃₁=d31/\sqrt{e33*s31}, where d₃₁ is the piezoelectric strain coefficient, e₃₃ is the dielectric permittivity in the thickness direction, and s₃₁ is the compliance in the machine direction. Higher values of k₃₁ may be achieved by disentangling polymer chains prior to stretching and promoting dipole moment alignment within a crystalline phase. In some embodiments, a polymer thin film may be characterized by an electromechanical coupling factor k₃₁ at room temperature of at least approximately 0.1, e.g., 0.1, 0.2, 0.3, or more, including ranges between any of the foregoing values.

In accordance with various embodiments, anisotropic polymer thin films may include amorphous polymer, aligned amorphous polymer, partially crystalline, or wholly crystalline materials. Such materials may also be mechanically anisotropic, where one or more characteristics selected from compressive strength, tensile strength, shear strength, yield strength, stiffness, hardness, toughness, ductility, machinability, thermal expansion, piezoelectric response, and creep behavior may be directionally dependent.

The crystalline content of a piezoelectric polymer thin film may include crystals of poly(vinylidene fluoride), poly(trifluoroethylene), poly(chlorotrifluoroethylene), poly(hexafluoropropene), and/or poly(vinyl fluoride), for example, although further crystalline polymer materials are contemplated, where a crystalline phase in a “crystalline” or “semi-crystalline” polymer thin film may, in some examples, constitute at least approximately 1% of the polymer thin film. For instance, the total beta phase content of a polymer thin film may be at least approximately 30%, e.g., 30, 40, 50, 60, 70, or 80%, including ranges between any of the foregoing values.

A piezoelectric polymer article such as a polymer thin film may, in some embodiments, have a Young's modulus along at least one in-plane direction (e.g., length or width) of at least approximately 4 GPa (e.g., 4 GPa, 10 GPa, 20 GPa, or 30 GPa or more, including ranges between any of the foregoing values). In some embodiments, a piezoelectric polymer thin film may have a Young's modulus along each of a pair of in-plane directions (e.g., length and width) that may independently be at least approximately 4 GPa (e.g., 4 GPa, 10 GPa, 20 GPa, or 30 GPa or more, including ranges between any of the foregoing values). A piezoelectric polymer thin film may be characterized by a piezoelectric coefficient along at least one direction of at least approximately 5 pC/N (e.g., 5 pC/N, 10 pC/N, 20 pC/N, 30 pC/N, or 40 pC/N or more, including ranges between any of the foregoing values).

In PVDF materials, a higher beta ratio may lead to a higher piezoelectric coefficient (d₃₁) and higher electromechanical coupling efficiency (k₃₁). The effect of composition on crystalline content (e.g., beta phase content) was evaluated for low and high molecular weight PVDF homopolymer resins following thin film formation and stretching/annealing of the thin films. As used herein, Composition A corresponds to a low viscosity (low molecular weight) PVDF homopolymer resin, and Composition B corresponds to a high viscosity (high molecular weight) PVDF homopolymer resin. The resins were tested independently and as mixtures that may be characterized by a bimodal molecular weight distribution. The sample descriptions and crystallization data are summarized in Table 1.

TABLE 1
Effect of Composition on Crystallinity in PVDF Thin Films

| Sample | #1 | #2 | #3 | #4 | #5 | Control |
|---|---|---|---|---|---|---|
| Amount A polymer, | 0 | 50 | 60 | 70 | 100 | Commercial |
| (balance B polymer) | | | | | | PVDF |
| [%] | | | | | | |
| Total crystallinity | 70 | 69 | 84 | 84 | 81 | 52 |
| [%] | | | | | | |
| Beta ratio [%] | 91 | 90 | 92 | 90 | 82 | 64 |
| Total beta phase | 64 | 62 | 77 | 75 | 66 | 33 |
| content [%] | | | | | | |
| Modulus [GPa] | 5.1 | 6.9 | 7.8 | 7.1 | 7.7 | 2.3 |
| Final stretch ratio | 9.9 | 11.6 | 11.1 | 10.6 | 12.6 | N/A |

The respective Compositions A and B (Samples 1 and 5) as well as mixtures thereof (Samples 2-4) were formed into thin films having a thickness of approximately 100 micrometers. The polymer thin films were than heated and stretched prior to measuring crystalline content. After heating the thin film samples to approximately 160° C., the thin films were stretched by applying a tensile stress that increased to a maximum of approximately 200 MPa. The thin films were drawn to a stretch ratio of approximately 9. Thereafter, while maintaining a constant applied stress (200 MPa), each thin film sample was annealed at approximately 160° C. for 20 min, heated at a ramp rate of 0.4° C./min to approximately 180° C. and annealed at approximately 180° C. for 30 min, and then heated at a ramp rate of 0.4° C./min to approximately 186° C. and annealed at approximately 186° C. for an additional 30 min. The samples were then cooled to below 35° C. under a constant applied stress of 200 MPa, and then the stress was removed.

After cooling, the total crystalline content was measured using differential scanning calorimetry (DSC), and the beta ratio was determined using Fourier Transform Infrared Spectroscopy (FTIR). As used herein, “beta ratio” refers to relative content of beta phase PVDF amongst the total crystalline content. The total beta phase content was calculated as the product of the total crystallinity and the beta ratio. The data indicate that the total beta phase content in the polymer thin films having a bimodal molecular weight distribution (Samples 2-4) may be greater than that in polymer thin films having a unimodal molecular weight distribution (Samples 1 and 5).

In some embodiments, a polymer thin film may have a total crystalline content of at least approximately 40%, e.g., at least approximately 40%, at least approximately 50%, at least approximately 60%, at least approximately 70%, at least approximately 80%, or at least approximately 90%, including ranges between any of the foregoing values. In some embodiments, a polymer thin film may have a beta ratio of at least approximately 70%, e.g., at least approximately 80%, at least approximately 85%, at least approximately 90%, or at least approximately 95%, including ranges between any of the foregoing values. In some embodiments, a polymer thin film may have a total beta phase content of at least approximately 30%, e.g., at least approximately 30%, at least approximately 40%, at least approximately 50%, at least approximately 60%, at least approximately 70%, or at least approximately 80%, including ranges between any of the foregoing values.

According to a further embodiment where the polymer thin films (e.g., Samples 1-5) are heated and stretched prior to measuring crystalline content, after heating the thin film samples to 160° C.±10° C., the thin films may be stretched by applying a tensile stress that is increased to a maximum of approximately 200 MPa. The thin films may be drawn to a stretch ratio of approximately 9. Thereafter, while maintaining a constant applied stress (200 MPa), each thin film sample may be annealed at 160° C.±10° C. for 20 min, heated at a ramp rate of 0.4° C./min to 180° C.±10° C. and annealed at 180° C.±10° C. for 30 min, and then heated at a ramp rate of 0.4° C./min to 186° C.±10° C. and annealed at 186° C.±10° C. for an additional 30 min. The samples may then be cooled to below 35° C. under a constant applied stress 200 MPa stress, and the stress removed.

The presently disclosed anisotropic PVDF-based polymer thin films may be characterized as optical quality polymer thin films and may form, or be incorporated into, an optical element as an actuatable layer. Optical elements may be used in various display devices, such as virtual reality (VR) and augmented reality (AR) glasses and headsets. The efficiency of these and other optical elements may depend on the degree of optical clarity and/or piezoelectric response.

According to various embodiments, an “optical quality thin film” or an “optical quality polymer thin film” may, in some examples, be characterized by a transmissivity within the visible light spectrum of at least approximately 20%, e.g., 20, 30, 40, 50, 60, 70, 80, 90, or 95%, including ranges between any of the foregoing values, and less than approximately 10% bulk haze, e.g., 0, 1, 2, 4, 6, or 8% bulk haze, including ranges between any of the foregoing values.

In further embodiments, an optical quality PVDF-based polymer thin film may be incorporated into a multilayer structure, such as the “A” layer in an ABAB multilayer. Further multilayer architectures may include AB, ABA, ABAB, or ABC configurations. Each B layer (and each C layer, if provided) may include a further polymer composition, such as polyethylene. According to some embodiments, the B (and C) layer(s) may be electrically conductive and may include, for example, indium tin oxide (ITO) or poly(3,4-ethylenedioxythiophene).

In a single layer or multilayer architecture, each PVDF-family layer may have a thickness ranging from approximately 100 nm to approximately 5 mm, e.g., 100, 200, 500, 1000, 2000, 5000, 10000, 20000, 50000, 100000, 200000, 500000, 1000000, 2000000, or 5000000 nm, including ranges between any of the foregoing values. A multilayer stack may include two or more such layers. In some embodiments, a density of a PVDF layer or thin film may range from approximately 1.7 g/cm³ to approximately 1.9 g/cm³, e.g., 1.7, 1.75, 1.8, 1.85, or 1.9 g/cm³, including ranges between any of the foregoing values.

According to some embodiments, the areal dimensions (i.e., length and width) of an anisotropic PVDF-family polymer thin film may independently range from approximately 5 cm to approximately 50 cm or more, e.g., 5, 10, 20, 30, 40, or 50 cm or more, including ranges between any of the foregoing values. Example piezoelectric polymer thin films may have areal dimensions of approximately 5 cm×5 cm, 10 cm×10 cm, 20 cm×20 cm, 50 cm×50 cm, 5 cm×10 cm, 10 cm×20 cm, 10 cm×50 cm, etc.

As used herein, the terms “polymer thin film” and “polymer layer” may be used interchangeably. Furthermore, reference to a “polymer thin film” or a “polymer layer” may include reference to a “multilayer polymer thin film” unless the context clearly indicates otherwise.

Aspects of the present disclosure thus relate to the formation of a single layer or multilayer polymer thin film having a high piezoelectric response and improved mechanical properties, including strength and toughness. The improved mechanical properties may also include improved dimensional stability and improved compliance in conforming to a surface having compound curvature, such as a lens.

Features from any of the embodiments described herein may be used in combination with one another in accordance with the general principles described herein. These and other embodiments, features, and advantages will be more fully understood upon reading the following detailed description in conjunction with the accompanying drawings and claims.

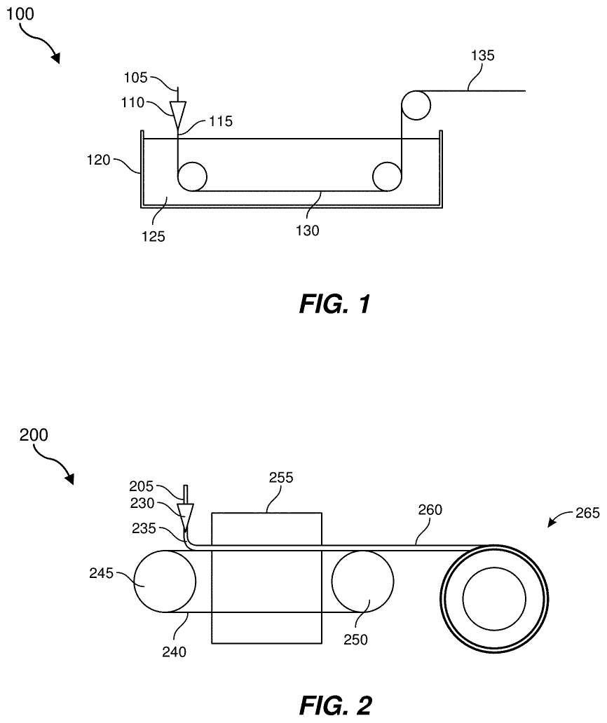

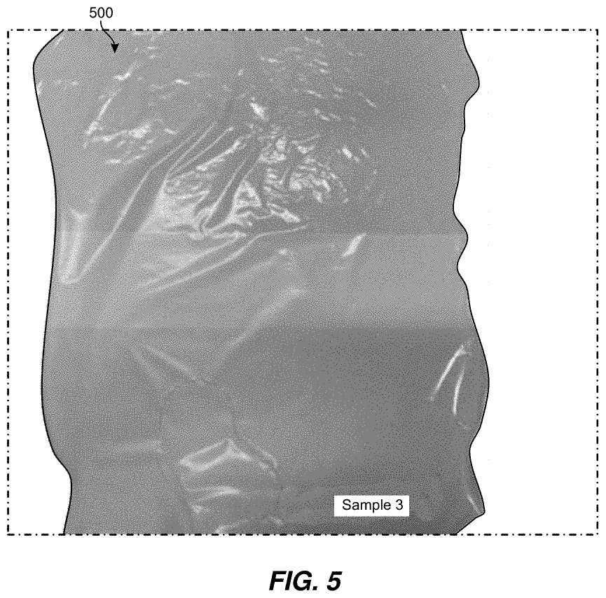

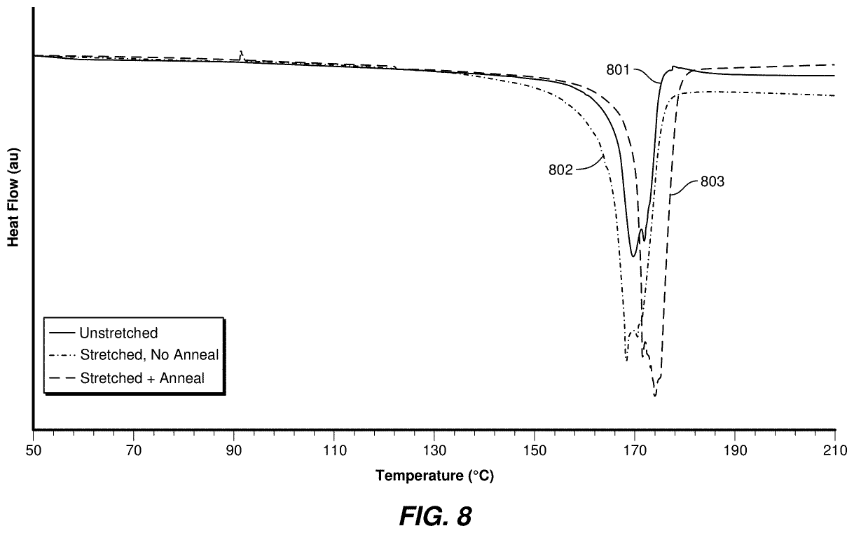

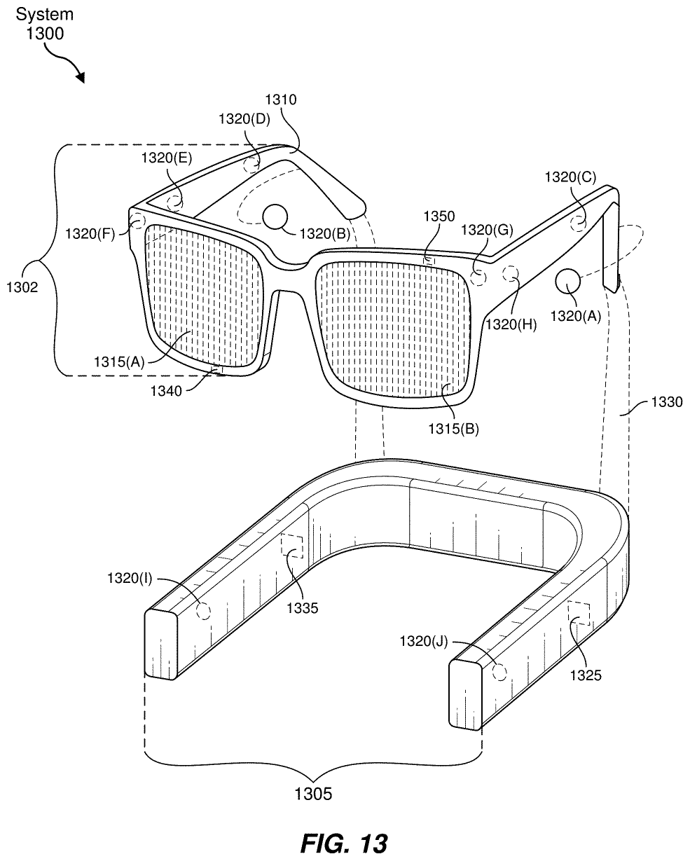

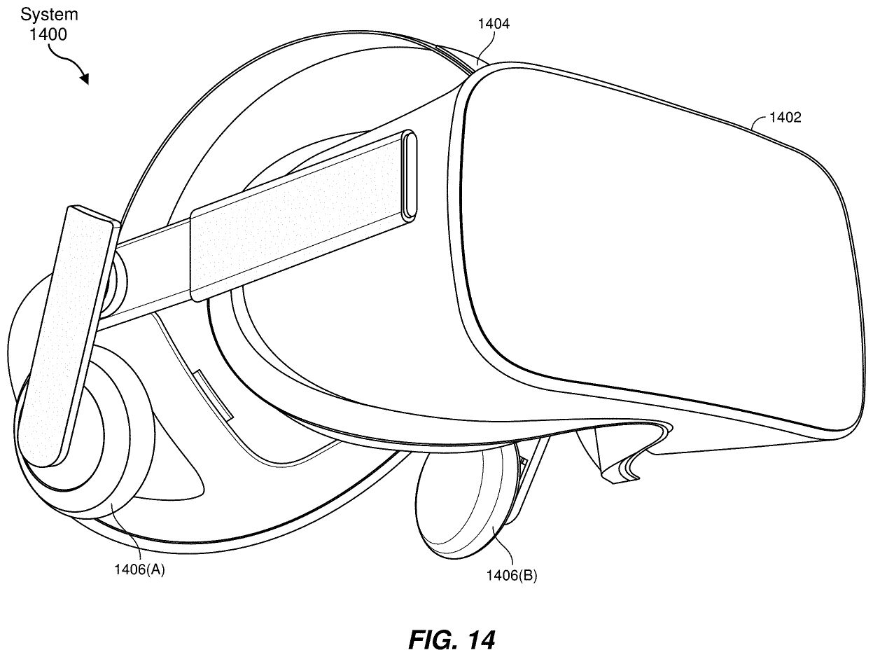

The following will provide, with reference to FIGS. 1-14, an overview of the manufacture and characterization of piezoelectric polymers having high polydispersity and high modulus, as well as concepts for incorporating such polymers into optical systems. The discussion associated with FIGS. 1-7 relates to example manufacturing paradigms for producing high strength and high modulus piezoelectric polyvinylidene fluoride thin films suitable for a variety of optical, mechanical, and optomechanical applications. The discussion associated with FIGS. 8-12 relates to the microstructural characterization and the attendant mechanical and piezoelectric response of piezoelectric polymer thin films. The discussion associated with FIGS. 13 and 14 relates to exemplary virtual reality and augmented reality devices that may include one or more piezoelectric polymer thin films.

In conjunction with various embodiments, a polymer thin film may be described with reference to three mutually orthogonal axes that are aligned with the machine direction (MD), the transverse direction (TD), and the normal direction (ND) of a thin film orientation system, and which may correspond respectively to the length, width, and thickness dimensions of the polymer thin film. Throughout various embodiments and examples of the instant disclosure, the machine direction may correspond to the x-direction of a polymer thin film, the transverse direction may correspond to the y-direction of the polymer thin film, and the normal direction may correspond to the z-direction of the polymer thin film.

A method for manufacturing a cast polymer thin film having low polymer chain entanglement is shown in FIG. 1. In method 100, one or more PVDF-family polymer resins (e.g., a high molecular weight polymer or a mixture containing a high molecular weight polymer and a low molecular weight polymer) is/are dissolved in a first solvent to form a feedstock solution. Pumping system 105 may be used to introduce the feedstock solution to a casting die 110.

As output from the casting die 110, a polymer layer 115 is fed into a vessel 120 containing a second solvent 125 that replaces the first solvent to form a crystalline polymer thin film 130. Cast and crystalline polymer thin film 135 is removed from the second solvent bath and dried. The cast thin film 135 may be sheeted or rolled for storage prior to stretching.

Referring to FIG. 2, shown schematically is a further method for forming a solvent cast polymer thin film. In method 200, one or more PVDF-family polymer resins (e.g., a high molecular weight polymer or a mixture containing a high molecular weight polymer and a low molecular weight polymer) is/are dissolved in a solvent to form a feedstock solution. Pumping system 205 may be used to introduce the feedstock solution to a casting die 230.

As output from the casting die 230, a layer 235 may be cast onto a carrier 240, such as a belt that is conveyed by rollers 245, 250. The rollers 245, 250 may transport the cast layer 235 through an oven 255 where the solvent may be removed at a removal rate effective to cause a desired degree of chain entanglement and corresponding properties in the polymer thin film 260. Polymer thin film 260 may be sheeted or rolled, e.g., onto roller 265, for storage prior to stretching.

According to some embodiments, in lieu of implementing a casting die 230, the feedstock solution may be coated onto carrier 240 using alternate methods, such as Mayer rod coating, doctor blading, gravure coating, transfer coating, and the like.

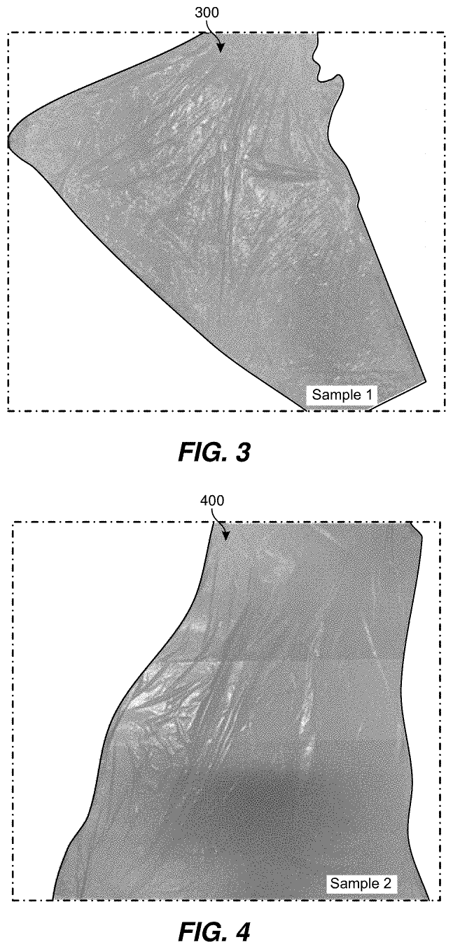

In an example solvent-based process, a high molecular weight PVDF homopolymer was dissolved in dimethylformamide (DMF) to form a 5 wt. % feedstock solution. The feedstock solution was cast onto a substrate and dried. Characteristics of three solvent-cast PVDF thin film samples are summarized in Table 2. Each polymer thin film was released from the substrate prior to stretching/orienting. Optical micrographs of comparative (pre-stretched) thin films 300, 400, 500 are shown in FIGS. 3-5, respectively.

TABLE 2
Characteristics of PVDF thin films formed by solvent-casting

| | | Drying | | |
|---|---|---|---|---|
| | | Temperature | | |
| | Solution | (C.) | Thickness | Haze |
| Sample1 | 5 wt % PVDF in DMF | RT | ~3 um | 9.53 |
| Sample2 | 5 wt % PVDF in DMF | 60 | ~10 um | 28.0-43.0 |
| Sample3 | 5 wt % PVDF in DMF | 60 | ~19 um- | 19.2-50.8 |
| | | | 40 um | |

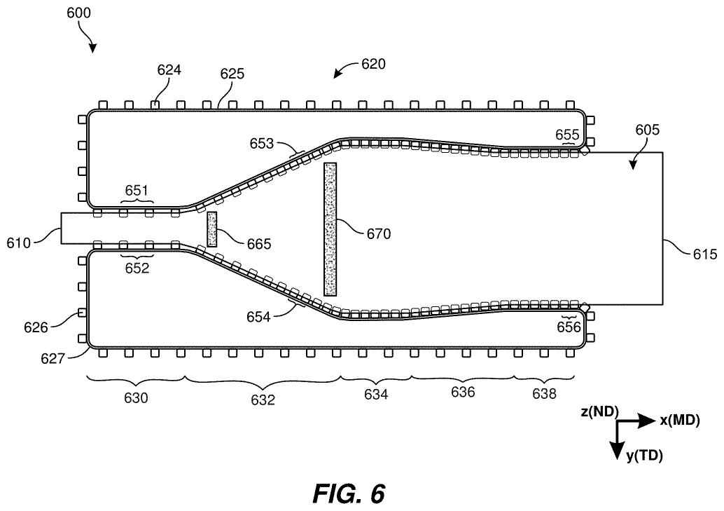

A thin film orientation system for forming an anisotropic piezoelectric polymer thin film is shown schematically in FIG. 6. System 600 may include a thin film input zone 630 for receiving and pre-heating a crystallizable portion 610 of a polymer thin film 605, a thin film output zone 638 for outputting a crystallized and oriented portion 615 of the polymer thin film 605, and a clip array 620 extending between the input zone 630 and the output zone 638 that is configured to grip and guide the polymer thin film 605 through the system 600, i.e., from the input zone 630 to the output zone 638. Clip array 620 may include a plurality of movable first clips 624 that are slidably disposed on a first track 625 and a plurality of movable second clips 626 that are slidably disposed on a second track 627.

Polymer thin film 605 may include a single polymer layer or multiple (e.g., alternating) layers of first and second polymers, such as a multilayer ABAB . . . structure. Alternately, polymer thin film 605 may include a composite architecture having a crystallizable polymer thin film and a high Poisson's ratio polymer thin film directly overlying the crystallizable polymer thin film (not separately shown). In some embodiments, a polymer thin film composite may include a high Poisson's ratio polymer thin film reversibly laminated to, or printed on, a single crystallizable polymer thin film or a multilayer polymer thin film.

During operation, proximate to input zone 630, clips 624, 626 may be affixed to respective edge portions of polymer thin film 605, where adjacent clips located on a given track 625, 627 may be disposed at an inter-clip spacing 651, 652, respectively. For simplicity, in the illustrated view, the inter-clip spacing 651 along the first track 625 within input zone 630 may be equivalent or substantially equivalent to the inter-clip spacing 652 along the second track 627 within input zone 630. As will be appreciated, in alternate embodiments, within input zone 630, the inter-clip spacing 651 along the first track 625 may be different than the inter-clip spacing 652 along the second track 627.

In addition to input zone 630 and output zone 638, system 600 may include one or more additional zones 632, 634, 636, etc., where each of: (i) the translation rate of the polymer thin film 605, (ii) the shape of first and second tracks 625, 627, (iii) the spacing between first and second tracks 625, 627, (iv) the inter-clip spacing 651-656, and (v) the local temperature of the polymer thin film 605, etc. may be independently controlled.

In an example process, as it is guided through system 600 by clips 624, 626, polymer thin film 605 may be heated to a selected temperature within each of zones 630, 632, 634, 636, 638. Fewer or a greater number of thermally controlled zones may be used. As illustrated, within zone 632, first and second tracks 625, 627 may diverge along a transverse direction such that polymer thin film 605 may be stretched in the transverse direction while being heated, for example, to a temperature greater than room temperature but less than the onset of melting. In some embodiments, a transverse stretch ratio (strain in the transverse direction/strain in the machine direction) may be approximately 6 or greater, e.g., 6, 8, 10, 15, 20, 25, or 30, including ranges between any of the foregoing values.

In accordance with certain embodiments, a polymer thin film may be stretched by a factor of 6 or more without fracture due at least in part to the high molecular weight of its component(s). In particular, high molecular weight polymers allow the thin film to be stretched at higher temperatures, which may decrease chain entanglement and produce a desirable combination of higher modulus, high transparency, and low haze in the stretched thin film.

Referring still to FIG. 6, within zone 632 the spacing 653 between adjacent first clips 624 on first track 625 and the spacing 654 between adjacent second clips 626 on second track 627 may decrease relative to the respective inter-clip spacing 651, 652 within input zone 630. In certain embodiments, the decrease in clip spacing 653, 654 from the initial spacings 651, 652 may scale approximately as the square root of the transverse stretch ratio. The actual ratio may depend on the Poisson's ratio of the polymer thin film as well as the requirements for the stretched thin film, including flatness, thickness, etc. Accordingly, in some embodiments, the in-plane axis of the polymer thin film that is perpendicular to the stretch direction may relax by an amount equal to the square root of the stretch ratio in the stretch direction. By decreasing the clip spacings 653, 654 relative to inter-clip spacings 651, 652, the polymer thin film may be allowed to relax along the machine direction while being stretched along the transverse direction. For instance, the polymer thin film may relax along the machine direction by at least approximately 10% of the Poisson's ratio of the polymer, e.g., 10, 20, 30, 40, 50, 60, 70, or 80% of the Poisson's ratio of the polymer thin film, including ranges between any of the foregoing values.

A temperature of the polymer thin film may be controlled within each heating zone. Within stretching zone 632, for example, a temperature of the polymer thin film 605 may be constant or independently controlled within sub-zones 665, 670, for example. In some embodiments, the temperature of the polymer thin film 605 may be decreased as the stretched polymer thin film 605 enters zone 634. Rapidly decreasing the temperature (i.e., thermal quenching) following the act of stretching within zone 632 may enhance the conformability of the polymer thin film 605. In some embodiments, the polymer thin film 605 may be thermally stabilized, where the temperature of the polymer thin film 605 may be controlled within each of the post-stretch zones 634, 636, 638. A temperature of the polymer thin film may be controlled by forced thermal convection or by radiation, for example, IR radiation, or a combination thereof.

Downstream of stretching zone 632, according to some embodiments, a transverse distance between first track 625 and second track 627 may remain constant or, as illustrated, initially decrease (e.g., within zone 634 and zone 636) prior to assuming a constant separation distance (e.g., within output zone 638). In a related vein, the inter-clip spacing downstream of stretching zone 632 may increase or decrease relative to inter-clip spacing 653 along first track 625 and inter-clip spacing 654 along second track 627. For example, inter-clip spacing 655 along first track 625 within output zone 638 may be less than inter-clip spacing 653 within stretching zone 632, and inter-clip spacing 656 along second track 627 within output zone 638 may be less than inter-clip spacing 654 within stretching zone 632. According to some embodiments, the spacing between the clips may be controlled by modifying the local velocity of the clips on a linear stepper motor line, or by using an attachment and variable clip-spacing mechanism connecting the clips to the corresponding track.

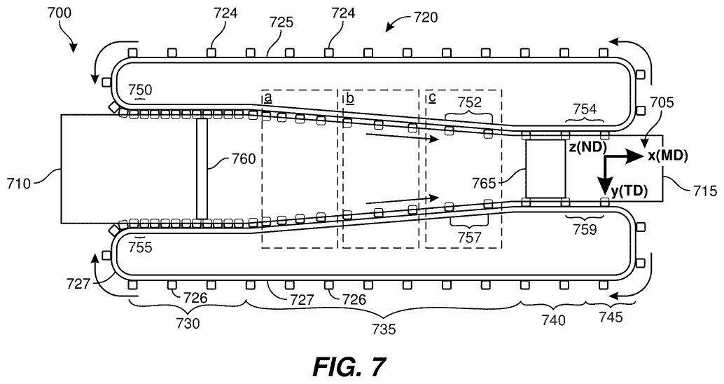

According to some embodiments, the stretched and oriented polymer thin film 615 may be removed from system 600 and further stretched in a subsequent stretching step, e.g., again using system 600, or via length orientation with relaxation as shown in FIG. 7. In example processes, a polymer thin film may be stretched one or more times, e.g., 1, 2, 3, 4, or 5 or more times.

Referring to FIG. 7, shown is a further example system for forming an anisotropic polymer thin film. Thin film orientation system 700 may include a thin film input zone 730 for receiving and pre-heating a crystalline or crystallizable portion 710 of a polymer thin film 705, a thin film output zone 745 for outputting an at least partially crystallized and oriented portion 715 of the polymer thin film 705, and a clip array 720 extending between the input zone 730 and the output zone 745 that is configured to grip and guide the polymer thin film 705 through the system 700. As in the previous embodiment, clip array 720 may include a plurality of first clips 724 that are slidably disposed on a first track 725 and a plurality of second clips 726 that are slidably disposed on a second track 727. In certain embodiments, crystalline or crystallizable portion 710 may correspond to stretched and oriented polymer thin film 615.

In an example process, proximate to input zone 730, first and second clips 724, 726 may be affixed to edge portions of polymer thin film 705, where adjacent clips located on a given track 725, 727 may be disposed at an initial inter-clip spacing 750, 755, which may be substantially constant or variable along both tracks within input zone 730. Within input zone 730 a distance along the transverse direction between first track 725 and second track 727 may be constant or substantially constant.

System 700 may additionally include one or more zones 735, 740, etc. The dynamics of system 700 allow independent control over: (i) the translation rate of the polymer thin film 705, (ii) the shape of first and second tracks 725, 727, (iii) the spacing between first and second tracks 725, 727 along the transverse direction, (iv) the inter-clip spacing 750, 755 within input zone 730 as well as downstream of the input zone (e.g., inter-clip spacings 752, 754, 757, 729), and (v) the local temperature of the polymer thin film, etc.

In an example process, as it is guided through system 700 by clips 724, 726, polymer thin film 705 may be heated to a selected temperature within each of zones 730, 735, 740, 745. A temperature greater than the glass transition temperature of a component of the polymer thin film 705 may be used during deformation (i.e., within zone 735), whereas a lesser temperature, an equivalent temperature, or a greater temperature may be used within each of one or more downstream zones.

As in the previous embodiment, the temperature of the polymer thin film 705 within stretching zone 735 may be locally controlled. According to some embodiments, the temperature of the polymer thin film 705 may be maintained at a constant or substantially constant value during the act of stretching. According to further embodiments, the temperature of the polymer thin film 705 may be incrementally increased within stretching zone 735. That is, the temperature of the polymer thin film 705 may be increased within stretching zone 735 as it advances along the machine direction. By way of example, the temperature of the polymer thin film 705 within stretching zone 735 may be locally controlled within each of heating zones a, b, and c.

The temperature profile may be continuous, discontinuous, or combinations thereof. As illustrated in FIG. 7, heating zones a, b, and c may extend across the width of the polymer thin film 705, and the temperature within each zone may be independently controlled according to the relationship room temperature <Tₐ<T_{b}<T_{c}<Tₘ. A temperature difference between neighboring heating zones may be less than approximately 20° C., e.g., less than approximately 10° C., or less than approximately 5° C.

Referring still to FIG. 7, within zone 735 the spacing 752 between adjacent first clips 724 on first track 725 and the spacing 757 between adjacent second clips 726 on second track 727 may increase relative to respective inter-clip spacings 750, 755 within input zone 730, which may apply an in-plane tensile stress to the polymer thin film 705 and stretch the polymer thin film along the machine direction. The extent of inter-clip spacing on one or both tracks 725, 727 within deformation zone 735 may be constant or variable and, for example, increase as a function of position along the machine direction.

Within stretching zone 735, the inner-clip spacings 752, 757 may increase linearly such that the primary mode of deformation may be at constant velocity. For example, a strain rate of the polymer thin film may decrease along the machine direction. In further embodiments, the polymer thin film 705 may be stretched at a constant strain rate where the inter-clip spacing may increase exponentially.

In certain examples, a progressively decreasing strain rate may be implemented. For instance, within stretching zone 735 an inter-clip spacing may be configured such that a distance between each successive pair of clips 724, 726 increases along the machine direction. The inter-clip spacing between each successive pair of clips may be independently controlled to achieve a desired strain rate along the machine direction.

In response to the tensile stress applied along the machine direction, first and second tracks 725, 727 may converge along a transverse direction within zone 735 such that polymer thin film 705 may relax in the transverse direction while being stretched in the machine direction. Using a single stretching step or multiple stretching steps, polymer thin film 705 may be stretched by a factor of at least approximately 4 (e.g., 4, 5, 6, 7, 8, 9, 10, 20, 40, 100, or more, including ranges between any of the foregoing values).

Within stretching zone 735, an angle of inclination of first and second tracks 725, 727 (i.e., with respect to the machine direction) may be constant or variable. In particular examples, the inclination angle within stretching zone 735 may decrease along the machine direction. That is, according to certain embodiments, the inclination angle within heating zone a may be greater than the inclination angle within heating zone b, and the inclination angle within heating zone b may be greater than the inclination angle within heating zone c. Such a configuration may be used to provide a progressive decrease in the relaxation rate (along the transverse direction) within the stretching zone 735 as the polymer thin film advances through system 700.

In some embodiments, the temperature of the polymer thin film 705 may be decreased as the stretched polymer thin film 705 exits zone 735. In some embodiments, the polymer thin film 705 may be thermally stabilized, where the temperature of the polymer thin film 705 may be controlled within each of the post-deformation zones 740, 745. A temperature of the polymer thin film may be controlled by forced thermal convection or by radiation, for example, IR radiation, or a combination thereof.

Downstream of deformation zone 735, the inter-clip spacing may increase or remain substantially constant relative to inter-clip spacing 752 along first track 725 and inter-clip spacing 757 along second track 727. For example, inter-clip spacing 754 along first track 725 within output zone 745 may be substantially equal to the inter-clip spacing 752 as the clips exit zone 735, and inter-clip spacing 759 along second track 727 within output zone 745 may be substantially equal to the inter-clip spacing 757 as the clips exit zone 735. Following the act of stretching, polymer thin film 705 may be annealed, for example, within one or more downstream zones 740, 745.

The strain impact of the thin film orientation system 700 is shown schematically by unit segments 760, 765, which respectively illustrate pre- and post-deformation dimensions for a selected area of polymer thin film 705. In the illustrated embodiment, polymer thin film 705 has a pre-stretch width (e.g., along the transverse direction) and a pre-stretch length (e.g., along the machine direction). As will be appreciated, a post-stretch width may be less than the pre-stretch width and a post-stretch length may be greater than the pre-stretch length.

In some embodiments, a roll-to-roll system may be integrated with a thin film orientation system, such as thin film orientation system 600 or thin film orientation system 700, to manipulate a polymer thin film. In further embodiments, a roll-to-roll system may itself be configured as a thin film orientation system.

As used herein, the terminology “engineering stress” may refer to a value equal to a force applied to a thin film divided by the thin film's initial cross-sectional area, whereas the terminology “real stress” may refer to an applied force divided by a dynamic cross-sectional area, i.e., an area determined during the act of stretching. To simplify the real stress calculation, the “real stress” reported herein is calculated as the quotient of the applied force and final cross-sectional area of a thin film, i.e., following the act of stretching.

Differential scanning calorimetry (DSC) endothermy associated with the melting of a polymer material having a bimodal molecular weight distribution (60% low molecular weight PVDF resin and 40% high molecular weight PVDF resin) are shown in FIG. 8. The data for an unstretched and unannealed PVDF thin film are depicted as curve 801. Curves 802 and 803 depict the melting endotherm for stretched, unannealed and stretched and annealed thin films, respectively.

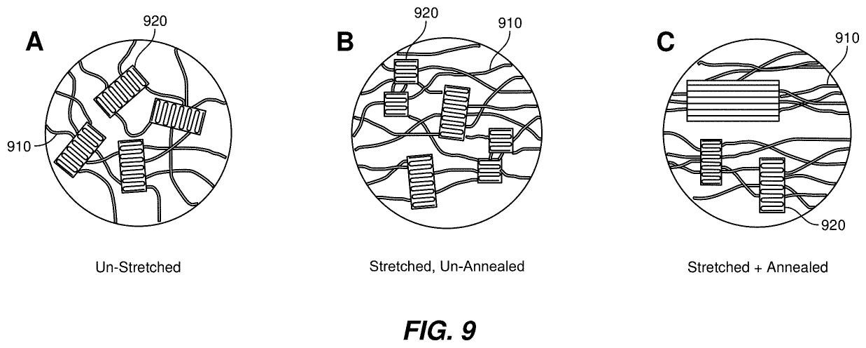

Without wishing to be bound by theory, the DSC data shown in FIG. 8 are consistent with the evolution in polymer chain alignment and crystal size depicted schematically in FIG. 9, which shows the microstructure of a PVDF thin film having a polymer matrix 910 and crystallites 920 dispersed throughout the matrix.

Referring initially to FIG. 9A, in an unstretched and unannealed state, an example polymer thin film is approximately 48% crystalline and, with reference also to FIG. 8, exhibits a primary endotherm 801 at approximately 170° C.

With the act of stretching, and with reference to FIG. 9B, strain-induced crystallization may increase the number of crystallites in the polymer thin film as polymer chains 910 align, but due to strain-induced fracture of some crystals 920, the average crystallite size may decrease relative to the unstrained state. As seen with reference again to FIG. 8, this microstructural transformation may shift the primary endotherm 802 for the stretched thin film to lower temperatures. The total crystalline content of the stretched and unannealed polymer thin film was calculated to be approximately 63%.

Referring now to FIG. 9C, following an annealing step under stress, both the average crystal size and the total crystalline content may increase, which, as shown in FIG. 8, is accompanied by a shift in the melting endotherm 803 to higher temperatures. The total crystalline content of the stretched and annealed polymer thin film was calculated to be approximately 84%.

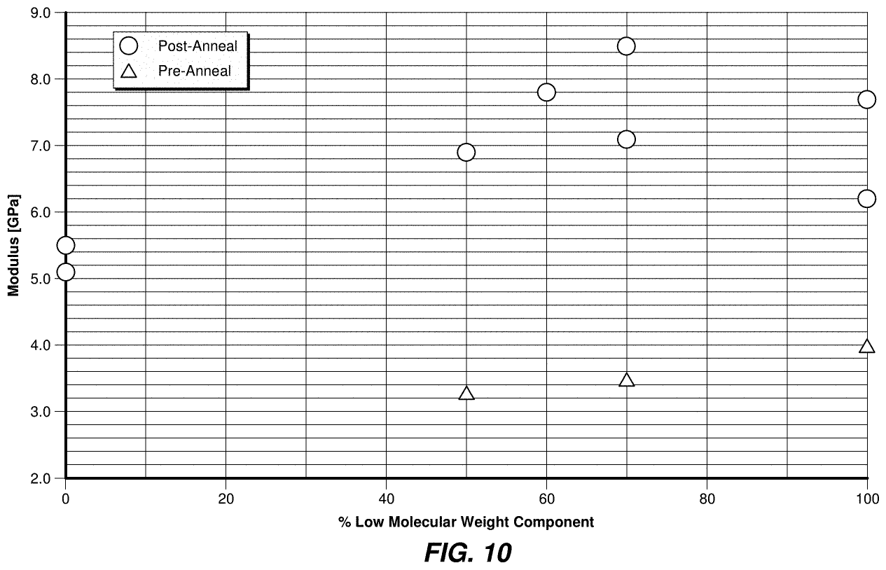

The effect of annealing and polymer composition on the modulus of example PVDF thin films is shown in FIGS. 10-12.

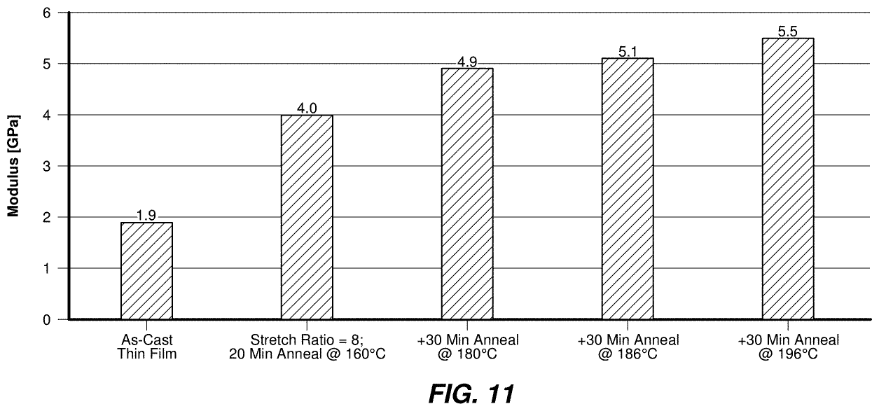

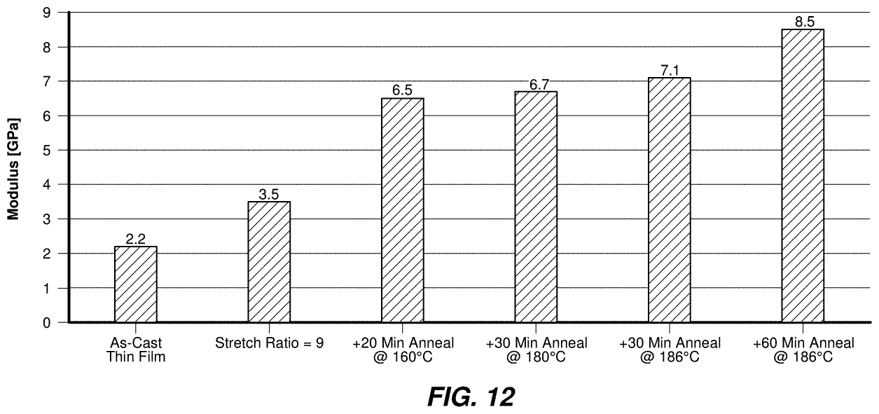

Modulus data for stretched polymer thin films having different PVDF compositions are plotted in FIG. 10. The effect of multi-step annealing is evident. The modulus of the post-annealed samples at different compositions may be greater than approximately 4 GPa, and is significantly greater than the modulus of the corresponding pre-annealed samples. Additional data showing the evolution of the modulus for samples having 0% low molecular weight component and 70% low molecular weight component are shown in FIGS. 11 and 12, respectively.

Referring to FIG. 11, stretching followed by multi-step annealing is shown to increase the modulus of a PVDF thin film formed from a high molecular weight polymer by as much as approximately 190% relative to the as-cast thin film. Through one or more annealing steps, a PVDF thin film formed from a high molecular weight polymer may have a modulus of at least approximately 4 GPa.

Referring to FIG. 12, stretching followed by multi-step annealing is shown to increase the modulus of a PVDF thin film formed from a bimodal molecular weight distribution by as much as approximately 290% relative to the as-cast thin film. The polymer composition includes 70% low molecular weight PVDF homopolymer resin and 30% high molecular weight PVDF homopolymer resin. Through one or more annealing steps, the PVDF thin film may have a modulus of at least approximately 6 GPa.

Disclosed are piezoelectric polymers and methods of manufacturing piezoelectric polymer thin films that exhibit an elevated modulus along at least one direction and an accompanying enhancement in their piezoelectric response. The piezoelectric response may be improved by stretching the polymer material to a very high stretch ratio, which may unfold elastic lamellar polymer crystals and reorient crystallites and/or polymer chains within the polymer matrix.

For many low molecular weight polymers, a requisite degree of stretching typically causes fracture or voiding that compromises optical quality. In addition, chain entanglement and high viscosity characteristic of high molecular weight polymers may limit their processability. Moreover, high stretch ratios may limit the maximum achievable thickness in stretched thin films. In accordance with various embodiments, Applicants have shown that high modulus thin films may be produced from a polydisperse mixture of suitable ultrahigh or high molecular weight materials and medium, low, or very low molecular weight miscible polymers, oligomers, or curable monomers.

The ratio of the ultrahigh and high MW component(s) to the medium to very low MW component(s) in example polymer systems may range from approximately 1:99 to approximately 99:1. In contrast to comparative polymer compositions, a stretch ratio greater than approximately 6 may be achieved. One or more annealing steps may increase the total beta phase content and/or crystallite size, which may increase the modulus of such thin film. Furthermore, stretching may be performed at higher temperatures, optionally in conjunction with exposure to actinic radiation, which may decrease the propensity for chain entanglement and enable the formation of thin films having a high modulus without inducing substantial opacity or haze. Example polymers may include PVDF and its copolymers such as PVDF-TrFE.

### EXAMPLE EMBODIMENTS

Example 1: A polymer thin film includes polyvinylidene fluoride (PVDF) and is characterized by a Young's modulus along an in-plane dimension of at least approximately 4 GPa, and an electromechanical coupling factor (k31) of at least approximately 0.1 at 25° C.

Example 2: The polymer thin film of Example 1, where the polyvinylidene fluoride includes a moiety selected from vinylidene fluoride (VDF), trifluoroethylene (TrFE), chlorotrifluoroethylene (CTFE), hexafluoropropene (HFP), vinyl fluoride (VF), and homopolymers, copolymers, tri-polymers, derivatives and mixtures thereof.

Example 3: The polymer thin film of any of Examples 1 and 2, where a composition of the polymer thin film is characterized by a bimodal molecular weight distribution.

Example 4: The polymer thin film of any of Examples 1 and 2, where a composition of the polymer thin film is characterized by a polydisperse molecular weight distribution.

Example 5: The polymer thin film of any of Examples 1-4, where the Young's modulus is at least approximately 4 GPa along each of a pair of mutually orthogonal in-plane dimensions.

Example 6: The polymer thin film of any of Examples 1-5, where the electromechanical coupling factor (k31) is at least approximately 0.15 at 25° C.

Example 7: The polymer thin film of any of Examples 1-6, where a piezoelectric coefficient (d31) of the polymer thin film is at least approximately 5 pC/N.

Example 8: The polymer thin film of any of Examples 1-7, where the polymer thin film is characterized by at least approximately 80% transparency at 550 nm and less than approximately 10% bulk haze.

Example 9: The polymer thin film of any of Examples 1-8, where the polymer thin film includes at least approximately 40% total crystalline content.

Example 10: The polymer thin film of any of Examples 1-9, where the polymer thin film includes at least approximately 30% total beta phase content.

Example 11: A polymer article is characterized by a Young's modulus along at least one dimension of at least approximately 4 GPa, an electromechanical coupling factor (k31) of at least approximately 0.1 at 25° C., and optical transparency along a thickness dimension of at least approximately 80%.

Example 12: The polymer article of Example 11, where the polymer article includes at least approximately 30% total beta phase content.

Example 13: A method includes forming a polymer composition into a polymer thin film, applying a tensile stress to the polymer thin film along at least one in-plane direction and in an amount effective to induce a stretch ratio of at least approximately 5 in the polymer thin film, and applying an electric field across a thickness dimension of the polymer thin film.

Example 14: The method of Example 13, where the forming includes a process selected from casting, extruding, molding, and calendaring.

Example 15: The method of any of Examples 13 and 14, where the polymer composition includes a mixture of a high molecular weight polymer and one or more of a low molecular weight polymer and an oligomer.

Example 16: The method of any of Examples 13-15, further including heating the polymer thin film while applying the tensile stress.

Example 17: The method of any of Examples 13-16, further including heating the polymer thin film to a temperature of at least 10° C. less than a melting peak temperature of the polymer composition while applying the tensile stress.

Example 18: The method of any of Examples 13-17, further including heating the polymer thin film after applying the tensile stress.

Example 19: The method of any of Examples 13-18, where the electric field is applied while applying the tensile stress or after applying the tensile stress.

Example 20: The method of any of Examples 13-19, where the electric field is applied while heating the polymer thin film or after heating the polymer thin film.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 1300 in FIG. 13) or that visually immerses a user in an artificial reality (such as, e.g., virtual-reality system 1400 in FIG. 14). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 13, augmented-reality system 1300 may include an eyewear device 1302 with a frame 1310 configured to hold a left display device 1315(A) and a right display device 1315(B) in front of a user's eyes. Display devices 1315(A) and 1315(B) may act together or independently to present an image or series of images to a user. While augmented-reality system 1300 includes two displays, embodiments of this disclosure may be implemented in augmented-reality systems with a single NED or more than two NEDs.

In some embodiments, augmented-reality system 1300 may include one or more sensors, such as sensor 1340. Sensor 1340 may generate measurement signals in response to motion of augmented-reality system 1300 and may be located on substantially any portion of frame 1310. Sensor 1340 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1300 may or may not include sensor 1340 or may include more than one sensor. In embodiments in which sensor 1340 includes an IMU, the IMU may generate calibration data based on measurement signals from sensor 1340. Examples of sensor 1340 may include, without limitation, accelerometers, gyroscopes, magnetometers, other suitable types of sensors that detect motion, sensors used for error correction of the IMU, or some combination thereof.

In some examples, augmented-reality system 1300 may also include a microphone array with a plurality of acoustic transducers 1320(A)-1320(J), referred to collectively as acoustic transducers 1320. Acoustic transducers 1320 may represent transducers that detect air pressure variations induced by sound waves. Each acoustic transducer 1320 may be configured to detect sound and convert the detected sound into an electronic format (e.g., an analog or digital format). The microphone array in FIG. 13 may include, for example, ten acoustic transducers: 1320(A) and 1320(B), which may be designed to be placed inside a corresponding ear of the user, acoustic transducers 1320(C), 1320(D), 1320(E), 1320(F), 1320(G), and 1320(H), which may be positioned at various locations on frame 1310, and/or acoustic transducers 1320(I) and 1320(J), which may be positioned on a corresponding neckband 1305.

In some embodiments, one or more of acoustic transducers 1320(A)-(J) may be used as output transducers (e.g., speakers). For example, acoustic transducers 1320(A) and/or 1320(B) may be earbuds or any other suitable type of headphone or speaker.

The configuration of acoustic transducers 1320 of the microphone array may vary. While augmented-reality system 1300 is shown in FIG. 13 as having ten acoustic transducers 1320, the number of acoustic transducers 1320 may be greater or less than ten. In some embodiments, using higher numbers of acoustic transducers 1320 may increase the amount of audio information collected and/or the sensitivity and accuracy of the audio information. In contrast, using a lower number of acoustic transducers 1320 may decrease the computing power required by an associated controller 1350 to process the collected audio information. In addition, the position of each acoustic transducer 1320 of the microphone array may vary. For example, the position of an acoustic transducer 1320 may include a defined position on the user, a defined coordinate on frame 1310, an orientation associated with each acoustic transducer 1320, or some combination thereof.

Acoustic transducers 1320(A) and 1320(B) may be positioned on different parts of the user's ear, such as behind the pinna, behind the tragus, and/or within the auricle or fossa. Or, there may be additional acoustic transducers 1320 on or surrounding the ear in addition to acoustic transducers 1320 inside the ear canal. Having an acoustic transducer 1320 positioned next to an ear canal of a user may enable the microphone array to collect information on how sounds arrive at the ear canal. By positioning at least two of acoustic transducers 1320 on either side of a user's head (e.g., as binaural microphones), augmented-reality device 1300 may simulate binaural hearing and capture a 3D stereo sound field around about a user's head. In some embodiments, acoustic transducers 1320(A) and 1320(B) may be connected to augmented-reality system 1300 via a wired connection 1330, and in other embodiments acoustic transducers 1320(A) and 1320(B) may be connected to augmented-reality system 1300 via a wireless connection (e.g., a BLUETOOTH connection). In still other embodiments, acoustic transducers 1320(A) and 1320(B) may not be used at all in conjunction with augmented-reality system 1300.

Acoustic transducers 1320 on frame 1310 may be positioned in a variety of different ways, including along the length of the temples, across the bridge, above or below display devices 1315(A) and 1315(B), or some combination thereof. Acoustic transducers 1320 may also be oriented such that the microphone array is able to detect sounds in a wide range of directions surrounding the user wearing the augmented-reality system 1300. In some embodiments, an optimization process may be performed during manufacturing of augmented-reality system 1300 to determine relative positioning of each acoustic transducer 1320 in the microphone array.

In some examples, augmented-reality system 1300 may include or be connected to an external device (e.g., a paired device), such as neckband 1305. Neckband 1305 generally represents any type or form of paired device. Thus, the following discussion of neckband 1305 may also apply to various other paired devices, such as charging cases, smart watches, smart phones, wrist bands, other wearable devices, hand-held controllers, tablet computers, laptop computers, other external compute devices, etc.

As shown, neckband 1305 may be coupled to eyewear device 1302 via one or more connectors. The connectors may be wired or wireless and may include electrical and/or non-electrical (e.g., structural) components. In some cases, eyewear device 1302 and neckband 1305 may operate independently without any wired or wireless connection between them. While FIG. 13 illustrates the components of eyewear device 1302 and neckband 1305 in example locations on eyewear device 1302 and neckband 1305, the components may be located elsewhere and/or distributed differently on eyewear device 1302 and/or neckband 1305. In some embodiments, the components of eyewear device 1302 and neckband 1305 may be located on one or more additional peripheral devices paired with eyewear device 1302, neckband 1305, or some combination thereof.

Pairing external devices, such as neckband 1305, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1300 may be provided by a paired device or shared between a paired device and an eyewear device, thus reducing the weight, heat profile, and form factor of the eyewear device overall while still retaining desired functionality. For example, neckband 1305 may allow components that would otherwise be included on an eyewear device to be included in neckband 1305 since users may tolerate a heavier weight load on their shoulders than they would tolerate on their heads. Neckband 1305 may also have a larger surface area over which to diffuse and disperse heat to the ambient environment. Thus, neckband 1305 may allow for greater battery and computation capacity than might otherwise have been possible on a stand-alone eyewear device. Since weight carried in neckband 1305 may be less invasive to a user than weight carried in eyewear device 1302, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1305 may be communicatively coupled with eyewear device 1302 and/or to other devices. These other devices may provide certain functions (e.g., tracking, localizing, depth mapping, processing, storage, etc.) to augmented-reality system 1300. In the embodiment of FIG. 13, neckband 1305 may include two acoustic transducers (e.g., 1320(I) and 1320(J)) that are part of the microphone array (or potentially form their own microphone subarray). Neckband 1305 may also include a controller 1325 and a power source 1335.

Acoustic transducers 1320(I) and 1320(J) of neckband 1305 may be configured to detect sound and convert the detected sound into an electronic format (analog or digital). In the embodiment of FIG. 13, acoustic transducers 1320(I) and 1320(J) may be positioned on neckband 1305, thereby increasing the distance between the neckband acoustic transducers 1320(I) and 1320(J) and other acoustic transducers 1320 positioned on eyewear device 1302. In some cases, increasing the distance between acoustic transducers 1320 of the microphone array may improve the accuracy of beamforming performed via the microphone array. For example, if a sound is detected by acoustic transducers 1320(C) and 1320(D) and the distance between acoustic transducers 1320(C) and 1320(D) is greater than, e.g., the distance between acoustic transducers 1320(D) and 1320(E), the determined source location of the detected sound may be more accurate than if the sound had been detected by acoustic transducers 1320(D) and 1320(E).

Controller 1325 of neckband 1305 may process information generated by the sensors on neckband 1305 and/or augmented-reality system 1300. For example, controller 1325 may process information from the microphone array that describes sounds detected by the microphone array. For each detected sound, controller 1325 may perform a direction-of-arrival (DOA) estimation to estimate a direction from which the detected sound arrived at the microphone array. As the microphone array detects sounds, controller 1325 may populate an audio data set with the information. In embodiments in which augmented-reality system 1300 includes an inertial measurement unit, controller 1325 may compute all inertial and spatial calculations from the IMU located on eyewear device 1302. A connector may convey information between augmented-reality system 1300 and neckband 1305 and between augmented-reality system 1300 and controller 1325. The information may be in the form of optical data, electrical data, wireless data, or any other transmittable data form. Moving the processing of information generated by augmented-reality system 1300 to neckband 1305 may reduce weight and heat in eyewear device 1302, making it more comfortable to the user.

Power source 1335 in neckband 1305 may provide power to eyewear device 1302 and/or to neckband 1305. Power source 1335 may include, without limitation, lithium ion batteries, lithium-polymer batteries, primary lithium batteries, alkaline batteries, or any other form of power storage. In some cases, power source 1335 may be a wired power source. Including power source 1335 on neckband 1305 instead of on eyewear device 1302 may help better distribute the weight and heat generated by power source 1335.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1400 in FIG. 14, that mostly or completely covers a user's field of view. Virtual-reality system 1400 may include a front rigid body 1402 and a band 1404 shaped to fit around a user's head. Virtual-reality system 1400 may also include output audio transducers 1406(A) and 1406(B). Furthermore, while not shown in FIG. 14, front rigid body 1402 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 1300 and/or virtual-reality system 1400 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 1300 and/or virtual-reality system 1400 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 1300 and/or virtual-reality system 1400 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a polymer thin film that comprises or includes polyvinylidene fluoride include embodiments where a polymer thin film consists essentially of polyvinylidene fluoride and embodiments where a polymer thin film consists of polyvinylidene fluoride.

What is claimed is:

1. A polymer thin film comprising polyvinylidene fluoride (PVDF) and characterized by:
a Young's modulus along an in-plane dimension of at least approximately 4 GPa; and
an electromechanical coupling factor (k₃₁) of at least approximately 0.1 at 25° C.

2. The polymer thin film of claim 1, wherein the polyvinylidene fluoride comprises a moiety selected from the group consisting of vinylidene fluoride (VDF), trifluoroethylene (TrFE), chlorotrifluoroethylene (CTFE), hexafluoropropene (HFP), vinyl fluoride (VF), and homopolymers, copolymers, tri-polymers, derivatives and mixtures thereof.

3. The polymer thin film of claim 1, wherein a composition of the polymer thin film is characterized by a bimodal molecular weight distribution.

4. The polymer thin film of claim 1, wherein a composition of the polymer thin film is characterized by a polydisperse molecular weight distribution.

5. The polymer thin film of claim 1, wherein the Young's modulus is at least approximately 4 GPa along each of a pair of mutually orthogonal in-plane dimensions.

6. The polymer thin film of claim 1, wherein the electromechanical coupling factor (k₃₁) is at least approximately 0.15 at 25° C.

7. The polymer thin film of claim 1, wherein a piezoelectric coefficient (d₃₁) of the polymer thin film is at least approximately 5 pC/N.

8. The polymer thin film of claim 1, wherein the polymer thin film is characterized by at least approximately 80% transparency at 550 nm and less than approximately 10% bulk haze.

9. The polymer thin film of claim 1, comprising at least approximately 40% total crystalline content.

10. The polymer thin film of claim 1, comprising at least approximately 30% total beta phase content.

11. A polymer article characterized by:
a Young's modulus along at least one dimension of at least approximately 4 GPa;
an electromechanical coupling factor (k₃₁) of at least approximately 0.1 at 25° C.; and
optical transparency along a thickness dimension of at least approximately 80%.

12. The polymer article of claim 11, comprising at least approximately 30% total beta phase content.

13. A method comprising:
forming a polymer composition into a polymer thin film;
applying a tensile stress to the polymer thin film along at least one in-plane direction and in an amount effective to induce a stretch ratio of at least approximately 5 in the polymer thin film; and
applying an electric field across a thickness dimension of the polymer thin film.

14. The method of claim 13, wherein the forming comprises a process selected from the group consisting of casting, extruding, molding, and calendaring.

15. The method of claim 13, wherein the polymer composition comprises a mixture of a high molecular weight polymer and one or more of a low molecular weight polymer and an oligomer.

16. The method of claim 13, further comprising heating the polymer thin film while applying the tensile stress.

17. The method of claim 13, further comprising heating the polymer thin film to a temperature of at least 10° C. less than a melting peak temperature of the polymer composition while applying the tensile stress.

18. The method of claim 13, further comprising heating the polymer thin film after applying the tensile stress.

19. The method of claim 13, wherein the electric field is applied while applying the tensile stress or after applying the tensile stress.

20. The method of claim 13, wherein the electric field is applied while heating the polymer thin film or after heating the polymer thin film.
